(19) United States
(12) Patent Application Publication
(10) Pub. No.: US 2025/0133829 A1
(43) Pub. Date: Apr. 24, 2025

(54) ARRAY SUBSTRATE, DISPLAY PANEL, AND METHOD FOR MANUFACTURING ARRAY SUBSTRATE

(71) Applicant: Sharp Display Technology Corporation, Kameyama City (JP)

(72) Inventors: Toshihiro KANEKO, Kameyama City (JP); Yoshinobu Nakamura, Kameyama City (JP); Tadayoshi Miyamoto, Kameyama City (JP)

(21) Appl. No.: 18/902,923

(22) Filed: Oct. 1, 2024

(30) Foreign Application Priority Data
Oct. 23, 2023 (JP) 2023-181887

(51) Int. Cl. H01L 27/12; G02F 1/1362; G02F 1/1368

(52) U.S. Cl. CPC H10D 86/60; G02F 1/136286; G02F 1/1368; H10D 86/0221; H10D 86/421; H10D 86/441

(57) ABSTRACT

An array substrate includes: a semiconductor film disposed on an upper-layer side of an insulating substrate; a gate insulating film disposed in a layer above the semiconductor film; a gate electrode disposed in a layer above the gate insulating film; an interlayer insulating film disposed in a layer above the gate electrode; a thin film transistor including a source electrode and a drain electrode disposed on the upper-layer side of the gate electrode via the interlayer insulating film; and a gate wiring line continuously formed with the gate electrode of the thin film transistor, wherein the gate electrode and the gate wiring line include an aluminum film, and a protective metal film made of a metal material having a melting point higher than a melting point of aluminum, and covering an entire surface of the aluminum film.

### CROSS-REFERENCE TO RELATED APPLICATIONS

This application claims the benefit of priority to Japanese Patent Application Number 2023-181887 filed on Oct. 23, 2023. The entire contents of the above-identified application are hereby incorporated by reference.

### BACKGROUND

### Technical Field

The present technology relates to an array substrate, a display panel, and a method for manufacturing the array substrate.

It is known that a thin film transistor (TFT) is used as a switching element in a display panel such as a liquid crystal panel or an organic electro-luminescence (EL) panel. The TFT is formed by layering various thin films on an array substrate (active matrix substrate, TFT substrate) constituting the display panel. JP 2003-8027 A discloses an example of a method for manufacturing the TFT.

The TFT described in JP 2003-8027 A is a so-called top gate type TFT, and a gate electrode and a gate wiring line have a three-layer structure in which titanium (Ti) layers are disposed above and below an aluminum (Al) layer. When an aluminum layer is used, wiring line resistance can be reduced. However, on the other hand, when the aluminum layer is subjected to heat treatment in a manufacturing process, defects (so-called hillocks or the like) are likely to occur due to moisture diffusion from a gate insulating film, or thermal reaction with an interlayer insulating film. Thus, in the TFT described in JP 2003-8027 A, an aluminum layer is sandwiched between titanium layers having a high melting point. In this way, even if heat treatment is performed at 400° C. in the manufacturing process, it is assumed that a situation in which a defect occurs in the aluminum layer can be suppressed.

### SUMMARY

However, 400° C. may be too low as the heat treatment temperature in the manufacturing process of the TFT. For example, in order to increase the screen size of an in-vehicle liquid crystal panel having a touch panel function, high stability is required for TFT characteristics. However, when the heat treatment temperature is less than 450° C., the TFT characteristics may vary and become unstable. More specifically, in a case where a polysilicon film (low temperature polycrystalline silicon (LTPS)) is used as a semiconductor film of the TFT, recovery of crystallinity of the polysilicon film becomes insufficient at a heat treatment temperature of less than 450° C., and defects may remain in the semiconductor film. In a TFT including a semiconductor film having defects, the TFT characteristics deteriorate and become unstable.

The technique described herein has been made based on the circumstances described above, and an object thereof is to achieve both reduction in wiring line resistance and stabilization of TFT characteristics.

(1) An array substrate according to the technique described herein includes a semiconductor film disposed on an upper-layer side of an insulating substrate, a gate insulating film disposed in a layer above the semiconductor film, a gate electrode disposed in a layer above the gate insulating film, an interlayer insulating film disposed in a layer above the gate electrode, a thin film transistor including a source electrode and a drain electrode disposed on the upper-layer side of the gate electrode via the interlayer insulating film, and a gate wiring line continuously formed with the gate electrode. The gate electrode and the gate wiring line include an aluminum film, and a protective metal film made of a metal material having a melting point higher than a melting point of aluminum, and covering an entire surface of the aluminum film.

(2) In addition to (1) described above, in the array substrate, the protective metal film may include an overlapping portion overlapping with the aluminum film, and a protruding portion protruding from the overlapping portion and not overlapping with the aluminum film, the semiconductor film may be an impurity semiconductor film, and of the semiconductor film, an impurity concentration in a first region overlapping with the overlapping portion of the protective metal film may be different from an impurity concentration in a second region overlapping with the protruding portion of the protective metal film.

(3) In addition to (2) described above, in the array substrate, the semiconductor film may have a structure including a channel region overlapping with the aluminum film of the gate electrode and the overlapping portion of the protective metal film, a source region and a drain region being high-concentration impurity regions disposed on both sides of the channel region, and being respectively connected to one of the source electrode and the drain electrode, and a low-concentration impurity region disposed in at least one of between the channel region and the source region and between the channel region and the drain region, and overlapping with the protruding portion of the protective metal film.

(4) In addition to any one of (1) to (3) described above, in the array substrate, the semiconductor film may be a polysilicon film.

(5) A display panel according to the technique described herein includes the array substrate according to any one of (1) to (4) described above, a counter substrate disposed to face the array substrate with an internal space provided between the array substrate and the counter substrate, and a liquid crystal layer sealed in the internal space.

(6) A method for manufacturing an array substrate according to the technique described herein includes forming a semiconductor film of a thin film transistor on an upper-layer side of an insulating substrate, forming a gate insulating film of the thin film transistor on the semiconductor film, forming a first metal film that is made of a metal material having a melting point higher than a melting point of aluminum and that forms, on the gate insulating film, a part of a gate electrode of the thin film transistor and a part of a gate wiring line connected to the gate electrode, forming an aluminum film that forms, on the first metal film, a part of the gate electrode and a part of the gate wiring line, patterning, by etching, a base layer including the formed first metal film and the formed aluminum film, forming a second metal film that is made of a metal having a melting point higher than the melting point of aluminum and that forms, on the patterned base layer, a part of the gate electrode and a part of the gate wiring line, patterning the formed second metal film by etching the second metal film to have a planar size larger than a planar size of the base layer, and forming the gate electrode and the gate wiring line including the base layer and the second metal film, and performing, after forming the gate electrode and the gate wiring line, heat treatment at a temperature equal to or higher than 450° C.

(7) In addition to (6) described above, in the method for manufacturing the array substrate, the semiconductor film may be an impurity semiconductor film, introduction of impurities may be performed, after forming the gate electrode and before performing the heat treatment, in which ionized impurities are accelerated and injected into the semiconductor film, and in the introduction of the impurities, a surface of the gate electrode may not be covered with another portion and may remain exposed.

(8) In addition to (6) or (7) described above, in the method for manufacturing the array substrate, the semiconductor film may be a polysilicon film, and when performing the heat treatment, crystallinity of the polysilicon film deteriorating due to the introduction of the impurities may be recovered.

According to the technique described herein, it is possible to achieve both reduction in wiring line resistance and stabilization of TFT characteristics.

### BRIEF DESCRIPTION OF DRAWINGS

The disclosure will be described with reference to the accompanying drawings, wherein like numbers reference like elements.

FIG. 1 is a schematic plan view of a liquid crystal panel according to a first embodiment.

FIG. 2 is a cross-sectional view of the liquid crystal panel.

FIG. 3 is an equivalent circuit diagram of a display pixel.

FIG. 4 is a cross-sectional view of a vicinity of a TFT in a GDM circuit portion of an array substrate.

FIG. 5 is a cross-sectional view of a vicinity of the TFT in a display region of the array substrate.

FIG. 6A is a diagram illustrating a manufacturing step of the array substrate illustrated in FIG. 4.

FIG. 6B is a diagram illustrating a manufacturing step of the array substrate subsequent to the manufacturing step illustrated in FIG. 6A.

FIG. 6C is a diagram illustrating a manufacturing step of the array substrate subsequent to the manufacturing step illustrated in FIG. 6B.

FIG. 6D is a diagram illustrating a manufacturing step of the array substrate subsequent to the manufacturing step illustrated in FIG. 6C.

FIG. 6E is a diagram illustrating a manufacturing step of the array substrate subsequent to the manufacturing step illustrated in FIG. 6D.

FIG. 6F is a diagram illustrating a manufacturing step of the array substrate subsequent to the manufacturing step illustrated in FIG. 6E.

FIG. 6G is a diagram illustrating a manufacturing step of the array substrate subsequent to the manufacturing step illustrated in FIG. 6F.

FIG. 6H is a diagram illustrating a manufacturing step of the array substrate subsequent to the manufacturing step illustrated in FIG. 6G (an enlarged cross-sectional view of the vicinity of the TFT in FIG. 4).

FIG. 7 is a cross-sectional micrograph of a vicinity of a gate electrode of an array substrate according to Comparative Example 1.

FIG. 8A is a diagram illustrating a manufacturing step of the array substrate according to Comparative Example 1.

FIG. 8B is a diagram illustrating a manufacturing step of the array substrate subsequent to the manufacturing step illustrated in FIG. 8A.

FIG. 8C is a diagram illustrating a manufacturing step of the array substrate subsequent to the manufacturing step illustrated in FIG. 8B.

FIG. 9 is a cross-sectional view of a vicinity of a TFT in an array substrate according to a second embodiment.

### DESCRIPTION OF EMBODIMENTS

### First Embodiment

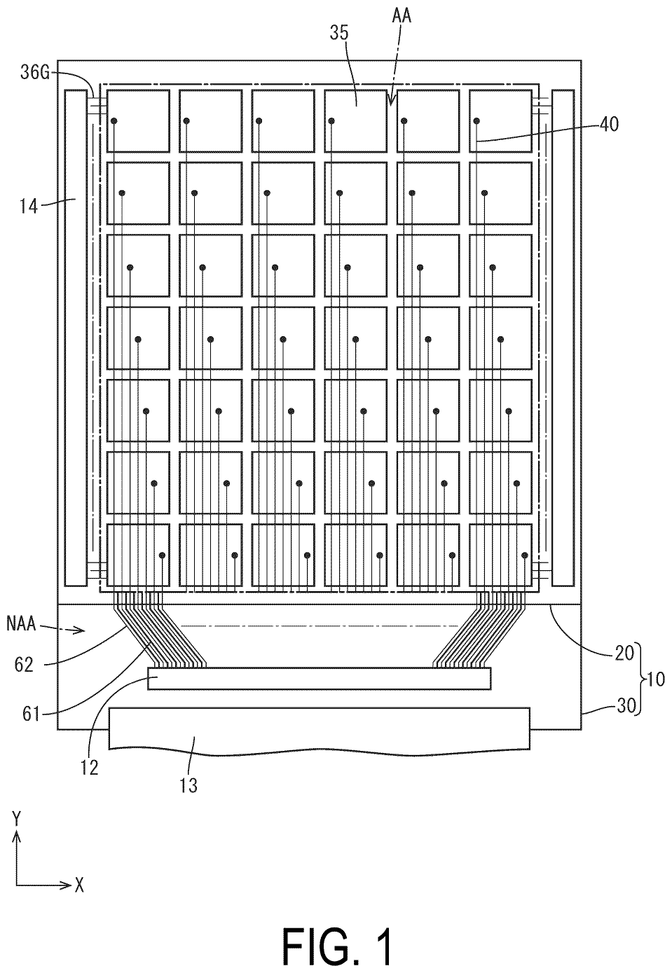

A liquid crystal panel 10 (an example of a display panel) according to a first embodiment will be described with reference to FIGS. 1 to 6H. Note that an X-axis, a Y-axis, and a Z-axis are illustrated in some of the drawings, and directions of these axes are drawn so as to be common in each of the drawings. In addition, a +Z-axis direction corresponds to a front side, and a −Z-axis direction corresponds to a back side.

As illustrated in FIG. 1, within the plane of the liquid crystal panel 10, the liquid crystal panel 10 is divided into a display region (active area) AA capable of displaying an image and disposed on the center side, and a non-display region (non-active area) NAA disposed on the outer circumference side and having a frame-like shape surrounding the display region AA in a plan view. In FIG. 1, a dot-dash line represents the contour of the display region AA, and a region outside the dot-dash line is the non-display region NAA. The planar shape of the liquid crystal panel 10 is not limited. In the present embodiment, the liquid crystal panel 10 has a vertically long rectangular shape as a whole with a short-side direction thereof coinciding with the X-axis direction, a long-side direction thereof coinciding with the Y-axis direction of the drawings, and a thickness direction thereof coinciding with the Z-axis direction.

In the non-display region NAA of the liquid crystal panel 10, a source driver 12 and two gate driver monolithic (GDM) circuit portions 14 are provided to drive the liquid crystal panel 10. The source driver 12 is an LSI type including a source drive circuit. The GDM circuit portion 14 is a gate drive circuit monolithically formed on an array substrate 30. The source driver 12 and the GDM circuit portion 14 are connected to a flexible substrate 13, one end portion of which is mounted in the non-display region NAA. The other end portion of the flexible substrate 13 is connected to an external control substrate, which is a supply source of various signals.

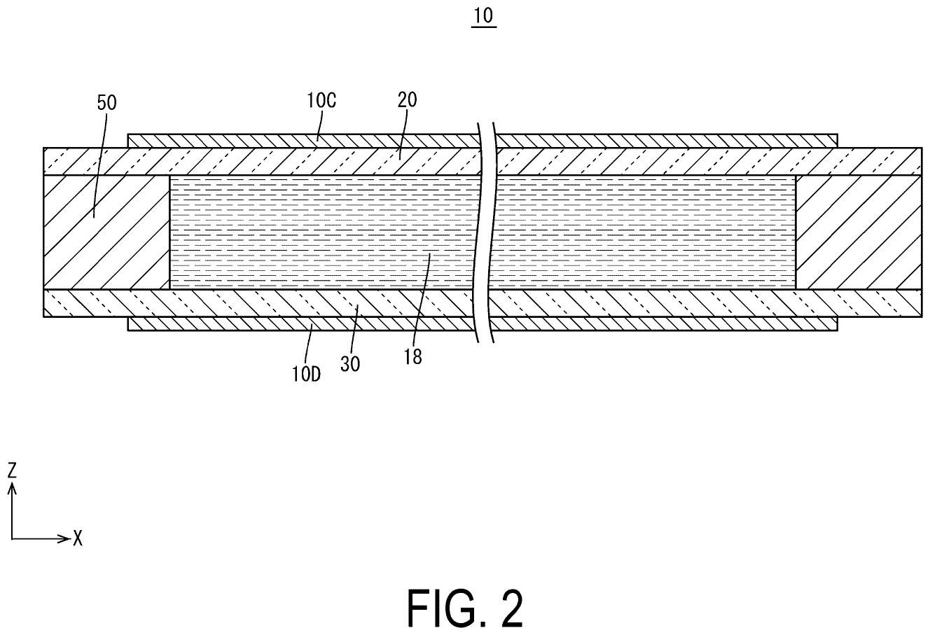

As illustrated in FIG. 2, the liquid crystal panel 10 includes two substrates 20 and 30 facing each other (an example of a display panel substrate), a liquid crystal layer 18, and a sealing portion 50. The liquid crystal layer 18 is sandwiched between the two substrates 20 and 30, and includes liquid crystal molecules that are a substance having optical characteristics changing in accordance with an applied electrical field. The sealing portion 50 is disposed in the non-display region NAA so as to surround the liquid crystal layer 18, is interposed between the two substrates 20 and 30, and seals the liquid crystal layer 18 while maintaining a cell gap corresponding to the thickness of the liquid crystal layer 18. A backlight device that irradiates the liquid crystal panel 10 with light is provided on the back side of the liquid crystal panel 10 (on the array substrate 30 side).

Of the two substrates 20 and 30, the substrate on the front side is a counter substrate (color filter substrate, CF substrate) 20, and the substrate on the back side is the array substrate 30. The counter substrate 20 and the array substrate 30 are each formed by layering various films on the liquid crystal layer 18 side of a glass substrate 31 (an example of an insulating substrate). Polarizers 10C and 10D are bonded to outer face sides (opposite sides from the liquid crystal layer 18) of the two substrates 20 and 30, respectively.

In the display region AA of the counter substrate 20, a large number of color filters are disposed side by side in a matrix shape. As for the color filters, colored films of three colors, namely, R (red), G (green), and B (blue) are repeatedly disposed side by side in a predetermined order. In the array substrate 30, pixel electrodes 34, which will be described later, are disposed at positions facing the respective colored films. One display pixel PX is constituted by a set of the three color colored films of R, G, and B and three of the pixel electrodes 34 facing the three color colored films, respectively.

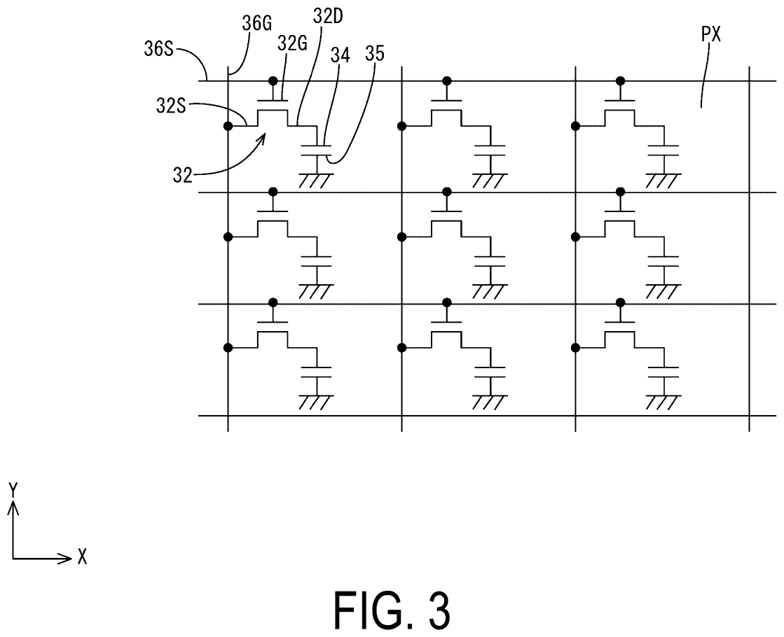

As illustrated in FIG. 3, in the display region AA of the array substrate 30, a large number of TFTs 32, which are switching elements, and a large number of the pixel electrodes 34 are provided side by side in a matrix shape. In addition, gate wiring lines (scanning lines) 36G and source wiring lines (data lines, signal lines) 36S are provided in a lattice pattern so as to surround the TFTs 32 and the pixel electrodes 34. As illustrated in FIG. 1, left and right end portions of the gate wiring lines 36G extend to the non-display region NAA and are connected to at least one of two GDM circuit portions 14. A gate voltage (scanning signal) is supplied to the gate wiring line 36G from the GDM circuit portion 14. The source wiring lines 36S are connected to the source driver 12 via first lead-out wiring lines 61 of the non-display region NAA. A data voltage (image signal) is supplied to the source wiring line 36S from the source driver 12.

As illustrated in FIG. 3, the TFT 32 includes a gate electrode 32G connected to the gate wiring line 36G, a source electrode 32S connected to the source wiring line 36S, and a drain electrode 32D connected to the pixel electrode 34. In addition, the TFT 32 includes a semiconductor film 33 having one end connected to the source electrode 32S and the other end connected to the drain electrode 32D. The TFT 32 is driven based on a gate signal supplied to the gate wiring line 36G. When a source signal is supplied to the source wiring line 36S during a gate writing period during which the gate signal is greater than a gate threshold voltage, a current flows between the source electrode 32S and the drain electrode 32D through a channel region 33C of the semiconductor film 33, and the pixel electrode 34 is charged to a potential corresponding to the source signal.

When a potential difference is generated between the pixel electrode 34 and a common electrode 35 to which a reference potential is applied, a fringe electrical field, including a component in a normal direction (Z-axis direction) with respect to the plate surface of the array substrate 30 in addition to a component along the plate surface (X-Y plane) of the array substrate 30, is applied to the liquid crystal layer 18. The fringe electrical field changes the alignment state of the liquid crystal molecules in the liquid crystal layer 18. As a result, the transmittance of light passing through the liquid crystal panel 10 changes, and the display state of the display pixel PX changes. Note that a driving method of the liquid crystal panel 10 is not limited to a fringe field switching (FFS) mode, and may be another method such as an in-plane switching (IPS) mode.

Further, the liquid crystal panel 10 may also be provided with a touch panel function of detecting an input position by a user. The liquid crystal panel 10 is an in-cell type touch panel including a configuration for realizing the touch panel function. The liquid crystal panel 10 uses a self-capacitance method as a detection method, but may use a mutual capacitance method.

As illustrated in FIG. 1, the common electrode 35 is divided into rectangles and disposed in a matrix shape in the display region AA, and also serves as a sensor electrode that detects the input position. When the user of the liquid crystal panel 10 brings a finger (a position input body serving as an electric conductor) close to the surface (display surface) of the liquid crystal panel 10, electrostatic capacitance is formed between the finger and the common electrode 35, and the input position is detected based on a change in the electrostatic capacitance. The common electrode (also serving as the sensor electrode) 35 is connected to a position detection circuit in the source driver 12 via a sensor wiring line 40 extending along the Y-axis direction in the display region AA, and via a second lead-out wiring line 62 of the non-display region NAA. The sensor wiring line 40 supplies, to the common electrode 35, a reference potential signal related to a display function and a position detection signal related to the touch panel function at different timings.

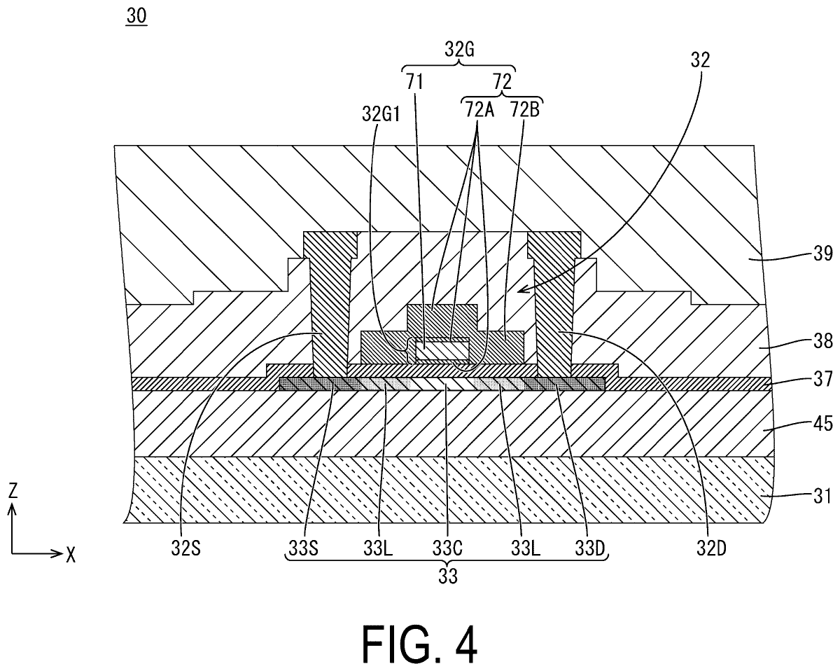

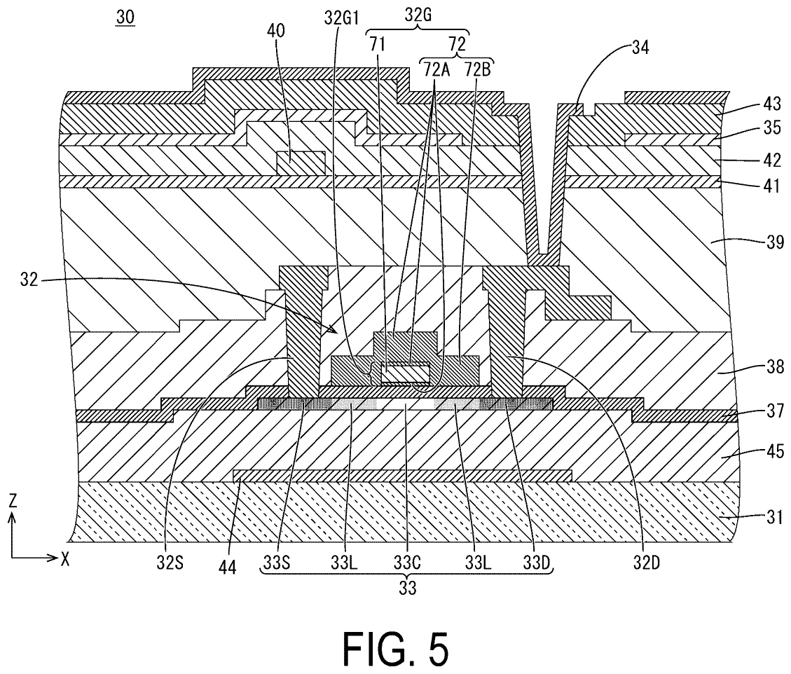

With reference to FIGS. 4 and 5, an example of a layer configuration of the array substrate 30 described above will be described. As illustrated in FIG. 4, in the array substrate 30, in the vicinity of the TFT 32 of the GDM circuit portion 14, a base coat film 45, the semiconductor film 33, a gate insulating film 37, the gate electrodes 32G, a first interlayer insulating film 38, the source electrodes 32S, and the drain electrodes 32D, and a flattening film 39 are layered in this order on the glass substrate 31. In addition, as illustrated in FIG. 5, in the array substrate 30, in the vicinity of the TFT 32 of the display region AA, a light blocking film 44, the base coat film 45, the semiconductor film 33, the gate insulating film 37, the gate electrodes 32G, the first interlayer insulating film 38, the source electrodes 32S and the drain electrodes 32D, the flattening film 39, a second interlayer insulating film 41, the sensor wiring lines 40, a third interlayer insulating film 42, the common electrode 35, a fourth interlayer insulating film 43, and the pixel electrodes 34 are layered in this order on the glass substrate 31. Further, an alignment film is applied to an uppermost layer (a layer closest to the liquid crystal layer 18) of the array substrate 30 so as to cover these various layered films.

The base coat film 45, the gate insulating film 37, the first interlayer insulating film 38, the second interlayer insulating film 41, the third interlayer insulating film 42, and the fourth interlayer insulating film 43 are each made of an inorganic insulating material such as silicon nitride (SiNₓ) or silicon oxide (SiO₂). The base coat film 45 is, for example, a two-layer film including a SiO₂ film having a thickness of about 200 nm and a SiNₓ film having a thickness of about 100 nm. The gate insulating film 37 is, for example, a two-layer film including a SiNₓ film having a thickness of about 50 nm and a SiO₂ film having a thickness of about 100 nm. The first interlayer insulating film 38 is, for example, a two-layer film including a SiNₓ film having a thickness of about 300 nm and a SiO₂ film having a thickness of about 300 nm. Each of the second interlayer insulating film 41 and the third interlayer insulating film 42 is, for example, a SiNₓ film having a thickness of about 100 nm. The fourth interlayer insulating film 43 is, for example, a SiNₓ film having a thickness of about 200 nm.

The flattening film 39 is made of a transparent organic insulating material such as an acrylic resin (PMMA or the like) or a polyimide resin, and has a film thickness larger than those of the other insulating films (the first interlayer insulating film 38 and the like). The flattening film 39 flattens the surface of the display region AA of the array substrate 30.

The light blocking film 44 is made of a metal film, for example, a molybdenum (Mo) film having a thickness of about 50 nm. The light blocking film 44 is disposed on the lower-layer side of the semiconductor film 33 via the base coat film 45, and overlaps with the semiconductor film 33. By providing the light blocking film 44, it is possible to suppress a change in characteristics of the TFT 32, which may occur when the semiconductor film 33 is irradiated with light from the backlight device.

The semiconductor film 33 is disposed on the lower-layer side of the gate electrode 32G via the gate insulating film 37, and overlaps with the gate electrode 32G. The semiconductor film 33 is an impurity semiconductor film formed by doping an intrinsic semiconductor film with impurities, and is made of a polysilicon film in the present embodiment. The semiconductor film 33 includes the channel region 33C (an example of a first region), a source region 33S, a drain region 33D, and a low-concentration impurity region 33L (an example of a second region). The semiconductor film 33 is formed so as to have different impurity concentrations in the channel region 33C, the low-concentration impurity region 33L, and a high-concentration impurity region (the source region 32S and the drain region 32D).

The channel region 33C of the semiconductor film 33 overlaps with an aluminum (Al) layer 71, which will be described later, of the gate electrode 32G, to prevent introduction of impurities in a manufacturing process. The source region 33S and the drain region 33D are arranged on both left and right sides of the channel region 33C, and impurities are introduced thereinto at a high concentration in the manufacturing process. The source region 33S and the drain region 33D are connected to the source electrodes 32S and the drain electrodes 32D, respectively.

The low-concentration impurity regions 33L of the semiconductor film 33 are formed between the channel region 33C and the source region 33S and between the channel region 33C and the drain region 33D. The low-concentration impurity region 33L is doped with impurities at a lower concentration than the channel region 33C and the source region 33S in the manufacturing process. Therefore, the TFT 32 is an n-channel MOSFET having a lightly doped drain (LDD) structure. The low-concentration impurity region 33L according to the present embodiment overlaps with a protruding portion 72B of a protective metal film 72, which will be described later, of the gate electrode 32G.

Note that an oxide semiconductor material (for example, indium gallium zinc oxide (IGZO)) or an amorphous silicon film may be used as the material of the semiconductor film 33. As in the present embodiment, when the polysilicon film is used, carrier mobility can be improved. As a result, the planar size of the TFT 32 can be reduced, and thus power consumption can be reduced due to frame narrowing and downsizing of the non-display region NAA. In addition, since the switching speed of the TFT 32 can be increased, display defects such as flickers and afterimages in the display region AA can be made less likely to occur.

The gate electrodes 32G and the gate wiring lines 36G are disposed in a layer above the gate insulating film 37. As illustrated in an example of the gate electrode 32G in FIGS. 4 and 5, the gate electrode 32G and the gate wiring line 36G each include the Al film 71 and the protective metal film 72. The protective metal film 72 is made of a metal material (for example, Mo or Ti) having a melting point higher than that of at least Al, and covers and protects the entire surface (all of the upper surface, the lower surface, and the side surfaces) of the Al film 71.

As illustrated in FIGS. 4 and 5, the protective metal film 72 has an overlapping portion 72A and the protruding portion 72B. The overlapping portion 72A overlaps with the Al film 71 and the channel region 33C of the semiconductor film 33. The protruding portion 72B protrudes from the overlapping portion 72A along the plate surface direction (X-Y plane), and does not overlap with the Al film 71 and the channel region 33C of the semiconductor film 33. The protruding portion 72B according to the present embodiment protrudes from the overlapping portion 72A to both the source electrode 32S side (the left side on the drawing) and the drain electrode 32D side (the right side on the drawing). However, as will be described later in a second embodiment, the protruding portion 72B may protrude to only one of the source electrode 32S side and the drain electrode 32D side. Specific materials and thicknesses of the respective portions of the gate electrode 32G and the gate wiring line 36G will be described in detail, in a description of a manufacturing method to be described later.

The source electrode 32S, the drain electrode 32D, the source wiring line 36S, and the sensor wiring line 40 are each made of a metal film. The source electrodes 32S, the drain electrodes 32D, and the source wiring lines 36S are disposed on the upper-layer side of the gate electrodes 32G and the gate wiring lines 36G via the first interlayer insulating film 38. Each of the source electrodes 32S, the drain electrodes 32D, and the source wiring lines 36S is, for example, a three-layer film in which a Ti film having a thickness of about 50 nm, an Al film having a thickness of about 350 nm, and a Ti film having a thickness of about 100 nm are layered in this order from the lower-layer side. The sensor wiring lines 40 are disposed in a layer above the second interlayer insulating film 41. Each of the sensor wiring lines 40 is, for example, a three-layer film in which a Mo film having a thickness of about 100 nm, an Al film having a thickness of about 300 nm, and a Mo film having a thickness of about 30 nm are layered in this order from the lower-layer side.

The pixel electrode 34 and the common electrode 35 are each made of a transparent electrode film (for example, indium tin oxide (ITO) or indium zinc oxide (IZO)). As illustrated in FIG. 5, the pixel electrode 34 penetrates layers between the pixel electrode 34 and the drain electrode 32D (specifically, the flattening film 39, the second interlayer insulating film 41, the third interlayer insulating film 42, and the fourth interlayer insulating film 43), and are connected to the drain electrode 32D.

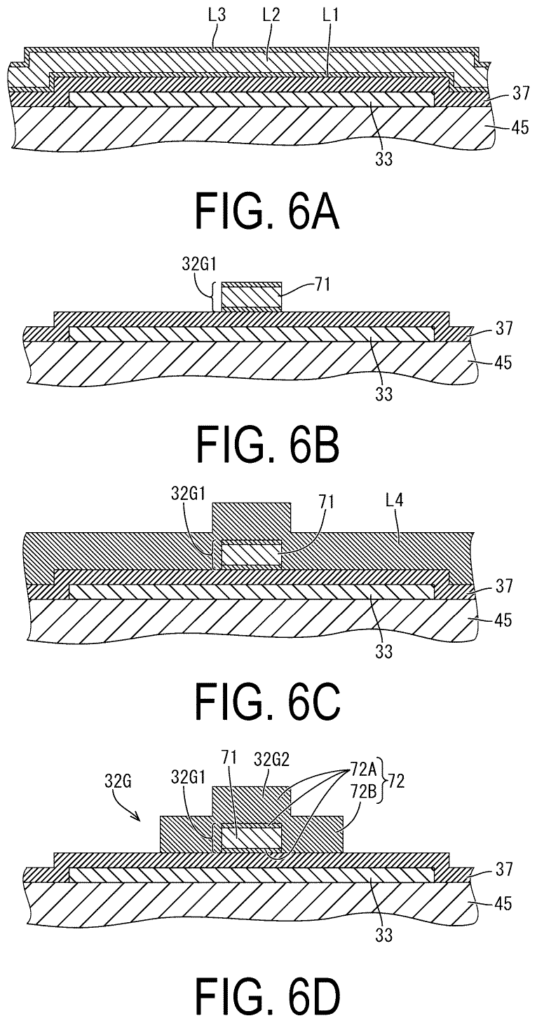

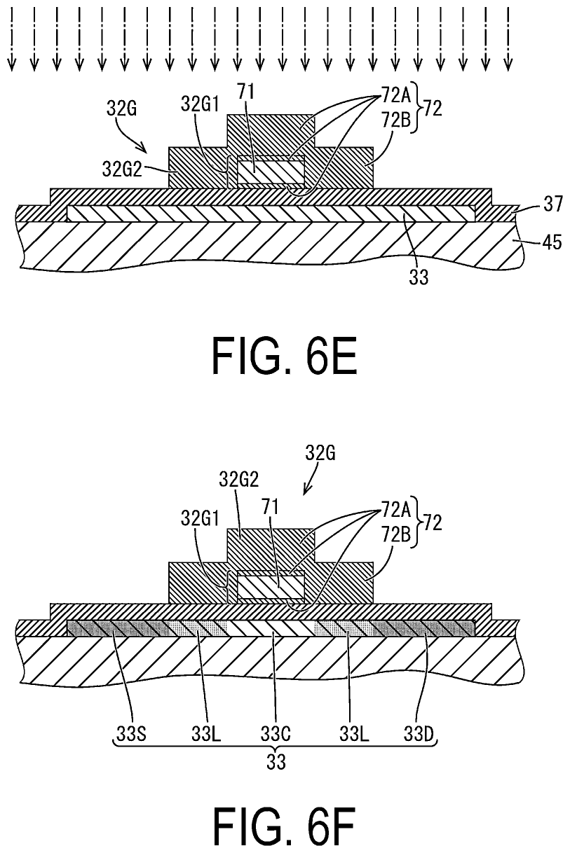

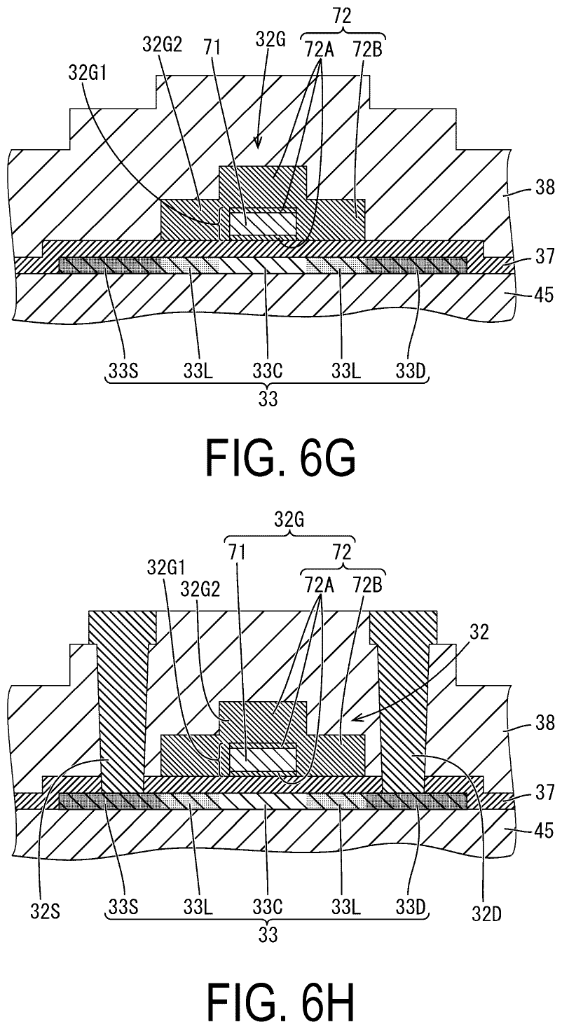

Next, a method for manufacturing the array substrate 30 will be described. Hereinafter, manufacturing steps after forming the base coat film 45 and before forming the flattening film 39 will be described in detail with reference to FIGS. 6A to 6H, by taking layering steps of a cross-sectional portion illustrated in FIG. 4 as an example.

As a method for forming the semiconductor film 33 on the base coat film 45 by patterning, a known manufacturing process can be used. More specifically, an amorphous silicon film is formed on the base coat film 45 by a CVD method or the like, and then heat treatment is performed at about 450° C. in a nitrogen atmosphere. The hydrogen concentration contained in the amorphous silicon film is reduced by the dehydrogenation heat treatment. The amorphous silicon film with the reduced hydrogen concentration is crystallized by excimer laser annealing (ELA) to form a polysilicon film. After that, the polysilicon film is patterned into a predetermined shape to form the semiconductor film 33 before impurity doping illustrated in FIG. 6A.

The gate insulating film 37 is formed on the patterned semiconductor film 33. On the formed gate insulating film 37, a lower-layer side first metal film L1, an Al film L2, and an upper-layer side first metal film L3 are formed in this order (FIG. 6A). The first metal films L1 and L3 come into contact with and protect the upper surface and the lower surface of the Al film L2 (the Al film 71 to be patterned at a later step). In contrast to the Al film L2 having a thickness of about 300 nm, the first metal films L1 and L3 are each made of, for example, Mo having a thickness of about 20 nm.

Subsequently, the layered first metal films L1 and L3 and the Al film L2 are patterned. The patterned three-layer films L1, L2, and L3 become a base layer 32G1 of the gate electrode 32G (FIG. 6B). A second metal film L4 is formed on the base layer 32G1 of the formed gate electrode 32G (FIG. 6C). The second metal film L4 is made of, for example, Mo having a thickness of about 500 nm. A cover layer 32G2 that covers the base layer 32G1 from above is formed by patterning the formed second metal film L4 so that the planar size of the second metal film L4 becomes larger than that of the base layer 32G1 (FIG. 6D).

When the gate electrodes 32G are formed in this manner, the patterned Al film L2 of the base layer 32G1 becomes the Al film 71 of the gate electrode 32G as illustrated in FIG. 6D. In addition, the patterned first metal films L1 and L3 of the base layer 32G1 and the cover layer 32G2 (patterned second metal film L4) become the protective metal film 72 of the gate electrode 32G.

However, a method for forming the gate electrode 32G is not limited to the manufacturing steps described above. For example, without forming the upper-layer side first metal film L3, a two-layer film including the lower-layer side first metal film L1 and the Al film L2 may be patterned to form the base layer 32G1, and the cover layer 32G2 may be formed so as to cover the base layer 32G1 from above.

Subsequently, impurity ions are injected into the semiconductor film 33 using the formed gate electrode 32G as a mask, to dope the semiconductor film 33 with impurities (FIG. 6E, introduction of impurities). In the introduction of the impurities, the surface of the gate electrode 32G is not covered with any other portion and remains exposed. A degree of the impurity injection into the semiconductor film 33 in the introduction of the impurities varies depending on the positional relationship between the semiconductor film 33 and the gate electrode 32G. More specifically, ions are injected at a high concentration into regions of the semiconductor film 33 that do not overlap with the gate electrode 32G, and those regions form the source region 33S and the drain region 33D having the highest impurity concentration (FIG. 6F). In addition, since an upper portion of a region of the semiconductor film 33 overlapping with the base layer 32G1 (Al film 71) of the gate electrode 32G is covered with a thick metal film, the introduction of the impurities is prevented, and the region becomes the channel region 33C having the lowest impurity concentration. On the other hand, a region of the semiconductor film 33 overlapping with the protruding portion 72B of the protective metal film 72 of the gate electrode 32G becomes the low-concentration impurity region 33L into which impurities are introduced at a low concentration, because the thickness of the metal film covering an upper portion of the region is thinner than that of the channel region 33C (FIG. 6F).

After doping the semiconductor film 33 with impurities, the first interlayer insulating film 38 is formed on the gate electrodes 32G (FIG. 6G). After forming the first interlayer insulating film 38, activation heat treatment is performed to recover (activate) the crystallinity of the semiconductor film 33 (polysilicon film) destroyed by the impurity doping (performing heat treatment). When performing the activation heat treatment, by heating the polysilicon film at a high heat treatment temperature of 450° C. or higher, it is possible to suppress a situation from occurring in which the recovery of the crystallinity of the polysilicon film becomes insufficient and defects remain.

After performing the activation heat treatment, the source electrode 32S and the drain electrode 32D are formed by patterning on the first interlayer insulating film 38 (FIG. 6H). A known manufacturing process can be used as a method for forming the source electrode 32S and the drain electrode 32D by patterning. The source electrode 32S and the drain electrode 32D are connected to the source region 33S and the drain region 33D of the semiconductor film 33, respectively, via contact portions penetrating between the layers.

Next, actions and effects of the above-described array substrate 30 and the above-described method for manufacturing the array substrate 30 will be described. The gate electrode 32G and the gate wiring line 36G according to the present embodiment each include the low-resistance Al film 71, and the protective metal film 72 made of a high-melting-point material. Since the wiring line resistance is reduced by the Al film 71, the signal transmission speed can be increased. In addition, since the entire surface of the Al film 71 is covered with the protective metal film 72, the Al film 71 can be protected by the protective metal film 72 even when the Al film 71 is heated at 450° C. or higher when performing the activation heat treatment in the manufacturing process.

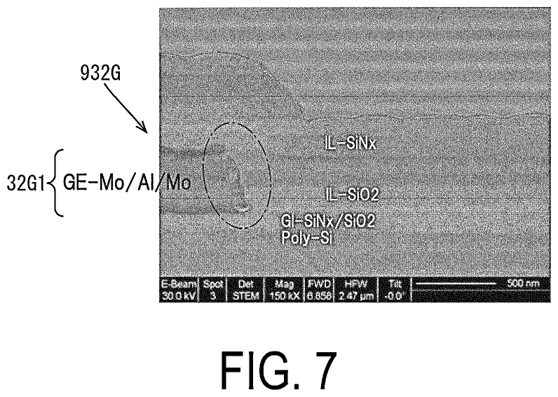

As in related art, if the gate electrode 32G and the gate wiring line 36G are made of only the base layer 32G1, and the side surfaces of the Al film 71 are not covered with the protective metal film 72, the side surfaces of the Al film 71 may thermally contract or may melt as a result of thermally reacting with the first interlayer insulating film 38 when the activation heat treatment is performed, as illustrated by a gate electrode 932G according to Comparative Example 1 in FIG. 7. As a result, hillocks (protrusions that cause a defect) are generated in the Al film 71, which cause unexpected leakage.

On the other hand, when the heating temperature at which the activation heat treatment is performed is lowered to less than 450° C. (for example, 400° C.) in order not to cause such a defect in the Al film 71, the recovery of the crystallinity of the semiconductor film 33 destroyed by the impurity doping becomes insufficient, and the TFT characteristics deteriorate and become unstable.

In contrast, according to the present embodiment, since the side surfaces of the Al film 71 are covered with the protective metal film 72, even when the Al film 71 is heated at 450° C. or higher, it is possible to suppress a situation from occurring in which the Al film 71 thermally contracts, or melts as a result of thermally reacting with the first interlayer insulating film 38. As a result, the activation heat treatment of the semiconductor film 33 can be performed at 450° C. or higher without causing a defect in the Al film 71, and the TFT characteristics of the semiconductor film 33 can be stabilized. Therefore, according to the array substrate 30 and the method for manufacturing the array substrate 30, it is possible to achieve both the reduction in the wiring line resistance and the stabilization of the TFT characteristics.

In addition, since the entire surface of the Al film 71 is covered with the protective metal film 72, it becomes easier to suppress a situation from occurring in which foreign matters are mixed into the Al film 71, or a patterning failure occurs in the manufacturing process.

The protective metal film 72 includes the overlapping portion 72A overlapping with the Al film 71 and the protruding portion 72B protruding from the overlapping portion 72A and not overlapping with the Al film 71. By using the protruding portion 72B of the protective metal film 72 as a mask in the impurity doping in the manufacturing process, the low-concentration impurity region 33L of the semiconductor film 33 can be easily formed. As a result, it is possible to easily form the TFT 32 having the LDD structure in which the impurity concentrations of the semiconductor film 33 are different in the channel region 33C, the low-concentration impurity region 33L, and the high-concentration impurity region (the source region 32S and the drain region 32D).

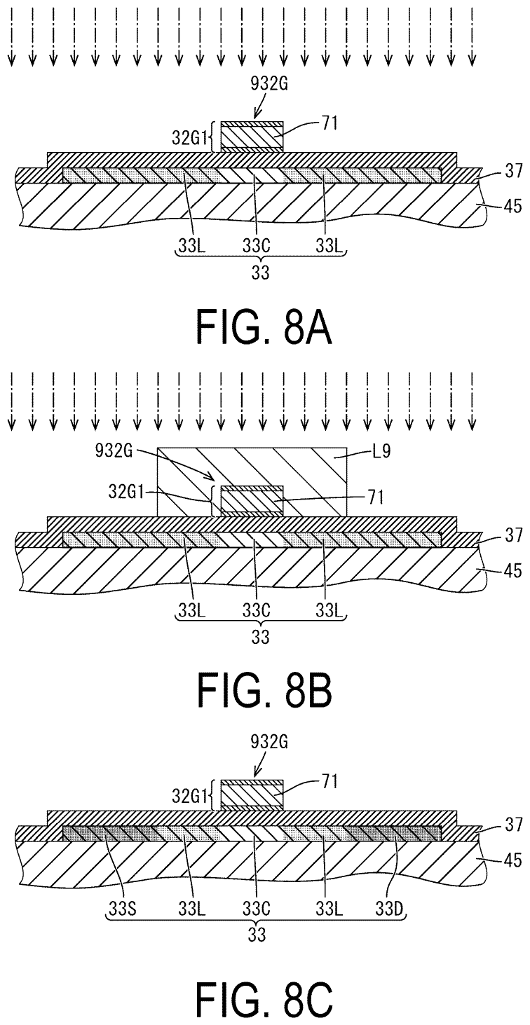

As in the related art, if the gate electrode 932G is constituted of only the base layer 32G1 and the protruding portion 72B of the protective metal film 72 is not provided, it is necessary to perform impurity ion injection (doping) twice in order to form the TFT having the LDD structure. For example, the first impurity ion injection is performed using the gate electrode 932G as a mask after the manufacturing step illustrated in FIG. 6C (FIG. 8A). At this time, since an upper portion of a region of the semiconductor film 33 overlapping with the base layer 32G1 (Al film 71) of the gate electrode 932G is covered with a thick metal film, the introduction of the impurities is prevented and the region becomes the channel region 33C having the lowest impurity concentration. On the other hand, a region of the semiconductor film 33 other than the channel region 33C becomes the low-concentration impurity region 33L into which impurities have been introduced.

After the first impurity doping, a photoresist L9 covering the upper surface and the side surfaces of the gate electrode 932G is formed, and the second impurity ion injection is performed using the photoresist L9 as a mask to perform the second impurity doping on the semiconductor film 33 (FIG. 8B). Regions of the semiconductor film 33 not overlapping with the photoresist L9 are subjected to ion injection once again, and thus become the source region 33S and the drain region 33D having the highest impurity concentration. After that, the photoresist L9 is removed (FIG. 8C), the first interlayer insulating film 38 is formed in the same manner as illustrated in FIG. 6G, and the source electrode 32S and the drain electrode 32D are formed in the same manner as illustrated in FIG. 6H. As a result, the TFT having the LDD structure is obtained.

Therefore, when the protruding portion 72B of the protective metal film 72 is not provided, it is necessary to perform the impurity doping twice to form and remove the photoresist L9 in order to form the low-concentration impurity region 33L and the high-concentration impurity region (the source region 33S and the drain region 33D) as described above. In this regard, according to the present embodiment, by utilizing the protruding portion 72B of the protective metal film 72 as a mask, the impurity doping is performed only once, and the step of forming and removing the photoresist L9 is not required.

Note that although a case where the polysilicon film is used as the semiconductor film 33 has been exemplified above, the present technology is also effective in a case where the impurity doping or the heat treatment is performed on an oxide semiconductor. In particular, the heat treatment temperature of the oxide semiconductor significantly influences the TFT characteristics. By covering the entire surface of the Al film 71 with the protective metal film 72, there is no restriction on the heat treatment temperature, and thus the TFT characteristics are easily improved and stabilized.

### Second Embodiment

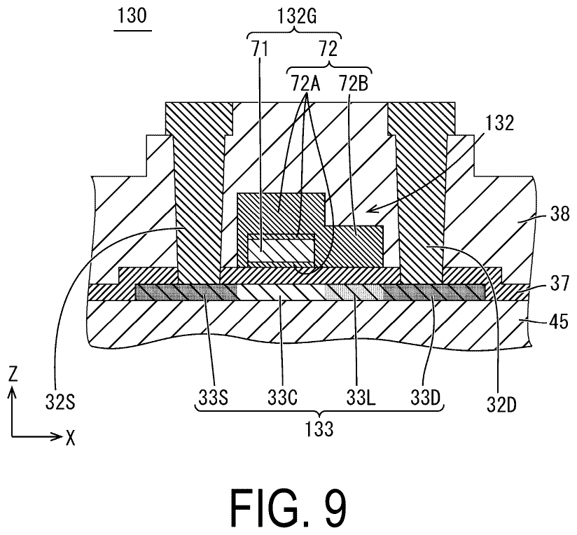

With reference to FIG. 9, a TFT 132 of an array substrate 130 according to a second embodiment will be described. The TFT 132 is different from the TFT of the first embodiment in that a protruding portion 172B of a protective metal film 172 of a gate electrode 132G protrudes from the overlapping portion 72A to only one side, namely, to only the drain electrode 32D side (the right side on the drawing). In the second embodiment, redundant descriptions of configurations, actions, and effects similar to those of the first embodiment will be omitted.

By providing the protruding portion 172B of the protective metal film 172 only on the one side, the low-concentration impurity region 33L of a semiconductor film 133 can be formed only on the side where the protruding portion 172B is provided. In the case of the present embodiment, since the protruding portion 172B is provided only on the drain electrode 32D side, the low-concentration impurity region 33L is formed only between the channel region 33C and the drain region 33D. As a result, the space for the TFT 132 can be reduced, saving space. In particular, since the current direction of the TFT 132 provided in the GDM circuit portion 14 is defined, the performance of the TFT 132 can be secured by forming the low-concentration impurity region 33L on the drain region 33D side, where there is concern about a deterioration in terms of reliability, and the space-saving can be achieved by not forming the low-concentration impurity region 33L on the source region 33S side.

### Other Embodiments

The technique described herein is not limited to the embodiments described above with reference to the drawings, and embodiments such as those described below are also included within the technical scope of the disclosure.

(1) The layer configuration and the layout pattern of the array substrate 30 are not limited to those illustrated in the drawings. The TFTs 32 and 132 formed in the GDM circuit portion 14 and the display region AA may not be of the same type, and may be a combination of different types having different configurations and/or in which the materials of the semiconductor films are different. Further, the TFTs 32 and 132 may be of a CMOS type in which an n-channel type and a p-channel type are combined.

(2) Depending on the driving method of the liquid crystal panel 10, the common electrode 35 may be provided at the counter substrate 20.

While preferred embodiments of the disclosure have been described above, it is to be understood that variations and modifications will be apparent to those skilled in the art without departing from the scope and spirit of the disclosure. The scope of the disclosure, therefore, is to be determined solely by the following claims.

1. An array substrate comprising:
a semiconductor film disposed on an upper-layer side of an insulating substrate;
a gate insulating film disposed in a layer above the semiconductor film;
a gate electrode disposed in a layer above the gate insulating film;
an interlayer insulating film disposed in a layer above the gate electrode;
a thin film transistor including a source electrode and a drain electrode disposed on the upper-layer side of the gate electrode via the interlayer insulating film; and
a gate wiring line continuously formed with the gate electrode of the thin film transistor,
wherein the gate electrode and the gate wiring line include an aluminum film, and a protective metal film made of a metal material having a melting point higher than a melting point of aluminum, and covering an entire surface of the aluminum film.

2. The array substrate according to claim 1,
wherein the protective metal film includes an overlapping portion overlapping with the aluminum film, and a protruding portion protruding from the overlapping portion and not overlapping with the aluminum film,
the semiconductor film is an impurity semiconductor film, and
of the semiconductor film, an impurity concentration in a first region overlapping with the overlapping portion of the protective metal film is different from an impurity concentration in a second region overlapping with the protruding portion of the protective metal film.

3. The array substrate according to claim 2,
wherein the semiconductor film has a structure including
a channel region overlapping with the aluminum film of the gate electrode and the overlapping portion of the protective metal film,
a source region and a drain region being high-concentration impurity regions disposed on both sides of the channel region, and being respectively connected to one of the source electrode and the drain electrode of the thin film transistor, and
a low-concentration impurity region disposed in at least one of between the channel region and the source region and between the channel region and the drain region, and overlapping with the protruding portion of the protective metal film.

4. The array substrate according to claim 1,
wherein the semiconductor film is a polysilicon film.

5. A display panel comprising:
the array substrate according to claim 1;
a counter substrate disposed to face the array substrate with an internal space provided between the array substrate and the counter substrate; and
a liquid crystal layer sealed in the internal space.

6. A method for manufacturing an array substrate, the method comprising:
forming a semiconductor film of a thin film transistor on an upper-layer side of an insulating substrate;
forming a gate insulating film of the thin film transistor on the semiconductor film;
forming a first metal film that is made of a metal material having a melting point higher than a melting point of aluminum and that forms, on the gate insulating film, a part of a gate electrode of the thin film transistor and a part of a gate wiring line connected to the gate electrode;
forming an aluminum film that forms, on the first metal film, a part of the gate electrode and a part of the gate wiring line;
patterning, by etching, a base layer including the formed first metal film and the formed aluminum film;
forming a second metal film that is made of a metal having a melting point higher than the melting point of aluminum and that forms, on the patterned base layer, a part of the gate electrode and a part of the gate wiring line;
patterning the formed second metal film by etching the second metal film to have a planar size larger than a planar size of the base layer, and forming the gate electrode and the gate wiring line including the base layer and the second metal film; and
performing, after forming the gate electrode and the gate wiring line, heat treatment at a temperature equal to or higher than 450° C.

7. The method for manufacturing the array substrate according to claim 6,
wherein the semiconductor film is an impurity semiconductor film,
introduction of impurities is performed, after forming the gate electrode and before performing the heat treatment, in which ionized impurities are accelerated and injected into the semiconductor film, and
in the introduction of the impurities, a surface of the gate electrode is not covered with another portion and remains exposed.

8. The method for manufacturing the array substrate according to claim 7,
wherein the semiconductor film is a polysilicon film, and
when performing the heat treatment, crystallinity of the polysilicon film deteriorating due to the introduction of the impurities is recovered.
